(19) United States
(12) Patent Application Publication
(10) Pub. No.: US 2025/0176293 A1
(43) Pub. Date: May 29, 2025

(54) DETECTION DEVICE

(71) Applicant: Japan Display Inc., Tokyo (JP)

(72) Inventors: Toshinori UEHARA, Tokyo (JP); Tomoyuki ISHIHARA, Tokyo (JP)

(21) Appl. No.: 18/961,860

(22) Filed: Nov. 27, 2024

(30) Foreign Application Priority Data
Nov. 28, 2023 (JP) 2023-200697

(51) Int. Cl. H10F 39/00; H10F 39/18

(52) U.S. Cl. CPC H10F 39/8063; H10F 39/8053; H10F 39/18

(57) ABSTRACT

According to an aspect, a detection device includes: an optical sensor including a plurality of photodetection elements arranged in a planar configuration; a light guide plate that is disposed on one side in a first direction of the optical sensor so as to overlap the optical sensor and has a light-transmitting property; a light source that is disposed adjacent to the light guide plate in a second direction intersecting the first direction and is configured to emit light to a side surface of the light guide plate; and a plurality of light scatterers that are arranged between the optical sensor and the light guide plate so as not to overlap the photodetection elements as viewed in the first direction and are configured to scatter the light propagating in the light guide plate.

### CROSS-REFERENCE TO RELATED APPLICATION

This application claims the benefit of priority from Japanese Patent Application No. 2023-200697 filed on Nov. 28, 2023, the entire contents of which are incorporated herein by reference.

### BACKGROUND

### 1. Technical Field

What is disclosed herein relates to a detection device.

### 2. Description of the Related Art

As disclosed in, for example, Japanese Patent Application Laid-open Publication No. 2019-045503 (JP-A-2019-045503) and Japanese Patent Application Laid-open Publication No. H11-120324 (JP-A-H11-120324), detection devices capable of detecting fingerprint patterns and vein patterns are known. The detection devices described in JP-A-2019-045503 and JP-A-H11-120324 are each provided with a front light on the front side of a plurality of photodiodes. That is, the front light is provided between an object to be detected such as a finger and the photodiodes. However, a part of light emitted from the front light that directly enters the photodiodes on the opposite side to the object to be detected may reduce contrast for detection.

Therefore, a structure is supposed in which the front light is configured such that a light source is provided on a lateral side of a light guide plate, and, for example, a light diffusion structure having a triangular section that is recessed toward the object to be detected is provided on a surface of a light guide plate facing the photodiodes. With this structure, light of the light source can enter the light guide plate from the lateral side thereof, and light propagating in the light guide plate can be applied on the light diffusion structure having a triangular section and caused to exit toward the object to be detected.

The light incident on the photodiodes includes: light that is incident on the photodiodes through the light guide plate from the object to be detected; and light that travels from the object to be detected, is refracted by the light diffusion structure, and is incident on the photodiodes. Thus, since the light incident on the photodiodes includes the light refracted by the light diffusion structure, the accuracy of detection may decrease.

For the foregoing reasons, there is a need for a detection device capable of achieving good accuracy of detection.

### SUMMARY

According to an aspect, a detection device includes: an optical sensor including a plurality of photodetection elements arranged in a planar configuration; a light guide plate that is disposed on one side in a first direction of the optical sensor so as to overlap the optical sensor and has a light-transmitting property; a light source that is disposed adjacent to the light guide plate in a second direction intersecting the first direction and is configured to emit light to a side surface of the light guide plate; and a plurality of light scatterers that are arranged between the optical sensor and the light guide plate so as not to overlap the photodetection elements as viewed in the first direction and are configured to scatter the light propagating in the light guide plate.

### BRIEF DESCRIPTION OF THE DRAWINGS

FIG. 1 is a schematic view illustrating a section of a detection device according to a first embodiment;

FIG. 2 is a schematic view illustrating a part of the section of the detection device according to the first embodiment;

FIG. 3 is a schematic view illustrating a part of FIG. 2;

FIG. 4A is a plan view of FIG. 1;

FIG. 4B is a sectional view taken along line IVB-IVB in FIG. 4A;

FIG. 5 is a block diagram illustrating a configuration example of the detection device according to the first embodiment;

FIG. 6 is a schematic diagram illustrating a manufacturing process of the detection device according to the first embodiment;

FIG. 7 is a schematic view illustrating a detection device according to a second embodiment;

FIG. 8 is a schematic view illustrating a detection device according to a first modification;

FIG. 9 is a schematic view illustrating a first light scatterer having a shape of a first taper;

FIG. 10 is a schematic view illustrating a second light scatterer having a shape of a second taper;

FIG. 11 is a schematic diagram illustrating a manufacturing process of the light scatterer using a white resist;

FIG. 12 is a schematic diagram illustrating the manufacturing process of the light scatterer using a black resist;

FIG. 13 is a plan view of the detection device according to the first modification;

FIG. 14 is a sectional view taken along XIV-XIV in FIG. 13;

FIG. 15 is a schematic view illustrating a detection device according to a second modification;

FIG. 16 is a schematic view illustrating a detection device according to a third modification;

FIG. 17 is a schematic view illustrating a detection device according to a third embodiment;

FIG. 18 is a schematic view illustrating a detection device according to a fourth embodiment;

FIG. 19 is a schematic view illustrating a light guide plate according to a fourth modification;

FIG. 20 is a schematic view illustrating a detection device according to a fifth embodiment;

FIG. 21 is a schematic view illustrating a spreading state of diffracted light;

FIG. 22 is a schematic view illustrating a detection device according to a sixth embodiment; and

FIG. 23 is a schematic view illustrating a detection device according to a fifth modification.

### DETAILED DESCRIPTION

The following describes modes (embodiments) for carrying out the present disclosure in detail with reference to the drawings. The present disclosure is not limited to the description of the embodiments given below. Components described below include those that are easily conceivable by those skilled in the art or those that are substantially identical thereto. In addition, the components described below can be combined as appropriate. What is disclosed herein is merely an example, and the present disclosure naturally encompasses appropriate modifications easily conceivable by those skilled in the art while maintaining the gist of the present disclosure.

To further clarify the description, the drawings may schematically illustrate, for example, widths, thicknesses, and shapes of various parts as compared with actual aspects thereof. However, they are merely examples, and interpretation of the present disclosure is not limited thereto. The same component as that described with reference to an already mentioned drawing is denoted by the same reference numeral through the present disclosure and the drawings, and detailed description thereof may not be repeated where appropriate.

In XYZ coordinates in the drawings, a Z direction (first direction) corresponds to the up-down direction; an X direction (second direction) corresponds to the left-right direction; and a Y direction corresponds to the front-rear direction. The X direction intersects (is orthogonal to) the Y and Z directions; the Y direction intersects (is orthogonal to) the X and Z directions; and the Z direction intersects (is orthogonal to) the X and Y directions. A Z1 side is one side in the first direction, and a Z2 side is the other side in the first direction. An X2 side is one side in the second direction, and an X1 side is the other side in the second direction.

### First Embodiment

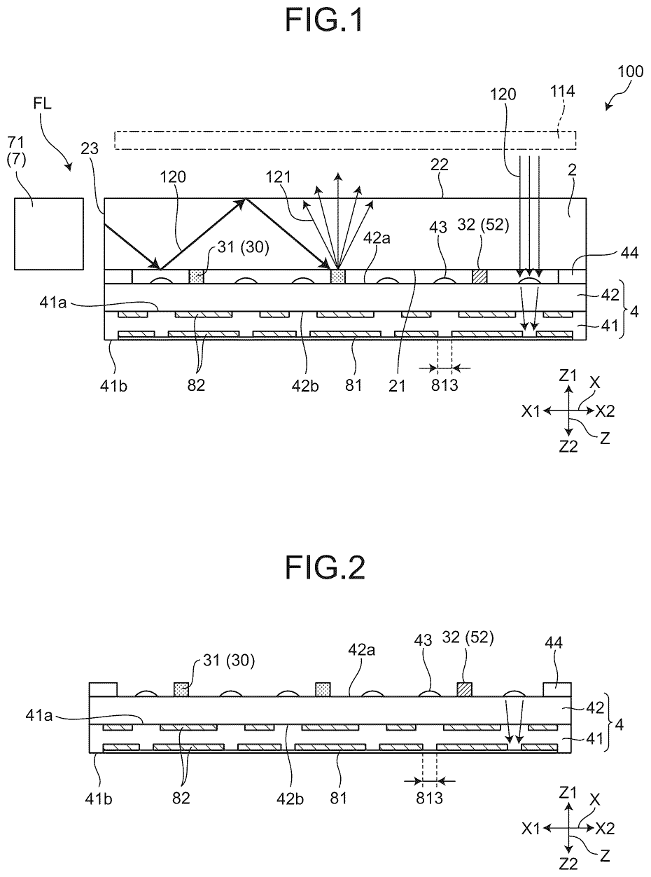

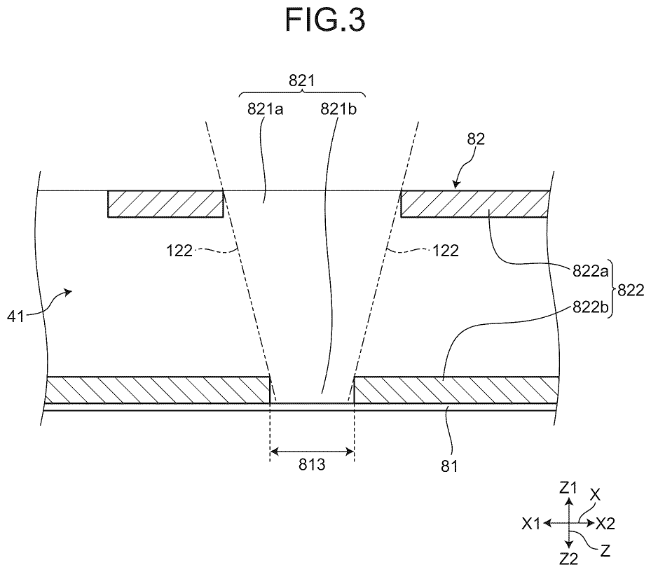

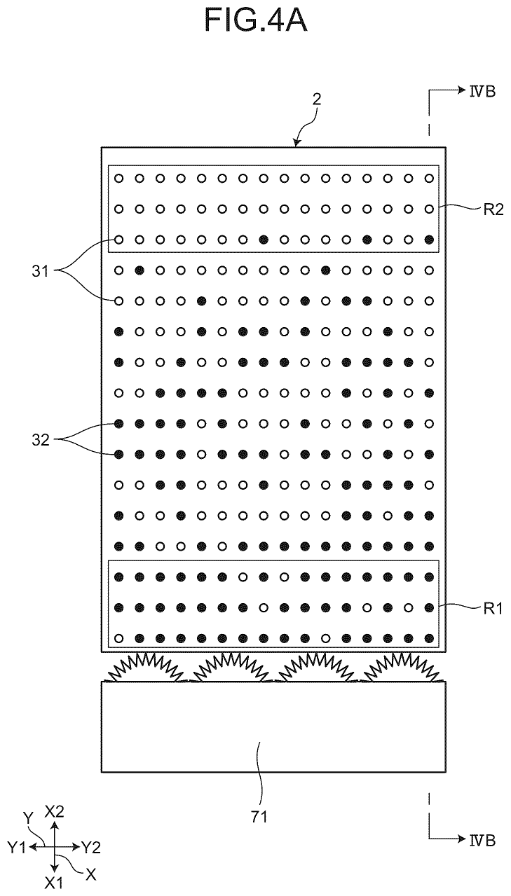

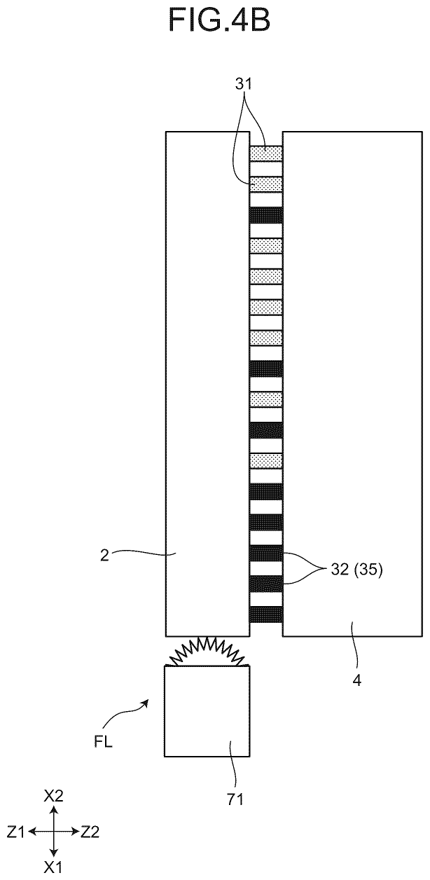

First, a first embodiment will be described. FIG. 1 is a schematic view illustrating a section of a detection device according to the first embodiment. FIG. 2 is a schematic view illustrating a part of the section of the detection device according to the first embodiment. FIG. 3 is a schematic view illustrating a part of FIG. 2. FIG. 4A is a plan view of FIG. 1 FIG. 4B is a sectional view taken along line IVB-IVB in FIG. 4A.

As illustrated in FIG. 1, a detection device 100 includes a front light FL, a sensor substrate 4, a light scatterer 30, and a microlens 43. The front light FL includes a light guide plate 2 and a light source device 7. The sensor substrate 4 includes an optical sensor 81 and an optical filter 82. That is, in other words, the detection device 100 includes the light guide plate 2, the light source device 7, the optical sensor 81, the optical filter 82, the light scatterer 30, and the microlens 43. An object to be detected 114 indicated by an imaginary line is located on the Z1 side (upper side, or one side in the first direction) of the light guide plate 2. Various types of objects are applicable as the object to be detected 114, including a container such as a Petri dish and a culture medium. The container and the culture medium will be described later.

As illustrated in FIG. 1, the light guide plate 2 is disposed on the Z1 side of the sensor substrate 4 so as to overlap the sensor substrate 4. The light guide plate 2 has a light-transmitting property. The light guide plate 2 is a flat plate-shaped member. The light guide plate 2 has a first surface 21, a second surface 22, and a side surface 23. The first surface 21 is a surface on the Z2 side, and the second surface 22 is a surface on the opposite side to the first surface 21 (that is, on the Z1 side thereof).

The side surface 23 is disposed on the X1 side The light source device 7 faces the side surface 23 of the light guide plate 2. The light source device 7 is disposed on the X1 side of the side surface 23 of the light guide plate 2. The light source device 7 emits light 120 to the side surface 23 of the light guide plate 2. The light source device 7 includes light sources 71 that are light-emitting diodes (LEDs), for example. That is, the light sources 71 are arranged along the Y direction and arranged so as to face the side surface 23 of the light guide plate 2.

As illustrated in FIGS. 1 and 2, the sensor substrate 4 includes a first light-transmitting plate 41, a second light-transmitting plate 42, the optical sensor 81, and the optical filter 82. The first light-transmitting plate 41 and the second light-transmitting plate 42 are light-transmitting flat plate-shaped members. The second light-transmitting plate 42 is stacked on top of the first light-transmitting plate 41. The first light-transmitting plate 41 has an upper surface 41a and a lower surface 41b. The second light-transmitting plate 42 has an upper surface 42a and a lower surface 42b.

As illustrated in FIG. 3, the first light-transmitting plate 41 is provided with the optical sensor 81 and the optical filter 82. The optical filter 82 is an optical element that transmits light components traveling toward the Z2 side out of the light 120 reflected by the object to be detected 114, toward the optical sensor 81. The optical filter 82 has a light guide path 821 and a light-blocking portion 822. The light guide path 821 has a light guide path 821a and a light guide path 821b. The light-blocking portion 822 has a light-blocking portion 822a and a light-blocking portion 822b. The light guide path 821a and the light-blocking portion 822a are disposed at an end on the Z1 side of the first light-transmitting plate 41 and extend in the X and Y directions. The light guide path 821b and the light-blocking portion 822b are disposed at an end on the Z2 side of the first light-transmitting plate 41 and extend in the X and Y directions. The light guide path 821a overlaps the light guide path 821b as viewed in the Z direction. The width in the X and Y directions of the light guide path 821a is larger than the width in the X and Y directions of the light guide path 821b. Therefore, a light path 122 from the light guide path 821a toward the light guide path 821b narrows toward the Z2 side. Thus, the optical filter 82 is an optical element that blocks components traveling in oblique directions. The optical filter 82 is also called collimating apertures, a louver, or a collimator.

The optical sensor 81 is partitioned into a plurality of photodiodes 813 (sensor pixels 812). Specifically, the photodiodes 813 are positive-intrinsic-negative (PIN) photodiodes or organic photodiodes (OPDs) using organic semiconductors. More specifically, as illustrated in FIG. 3, one photodiode 813 is disposed on the Z2 side so as to face the light guide path 821b.

As illustrated in FIGS. 1 and 2, the microlens 43 is provided on the upper surface 42a of the second light-transmitting plate 42. The microlens 43 is a hemispherical light-transmitting member that projects from the upper surface 42a towards the Z1 side. That is, the microlens 43 has a circular shape as viewed in the Z direction. The microlens 43 focuses the light 120 from the object to be detected 114 onto photodiode 813. As viewed in the Z direction, the microlens 43 overlaps the light guide path 821a, the light guide path 821b, and the photodiode 813 illustrated in FIG. 3.

The light scatterer 30 is a white resist 31, for example. The white resist 31 scatters part of the light 120 propagating in the light guide plate 2. The white resist 31 is applied to the upper surface 42a of the second light-transmitting plate 42. The white resist 31 has, for example, a columnar shape extending in the Z direction.

As illustrated in FIGS. 4A and 4B, the density of the white resists 31 that are the light scatterers 30 increases as distance from the light sources 71 increases. In other words, the density of white resists 31 increases from the X1 side toward the X2 side. Specifically, as illustrated in FIG. 4A, the number of the white resists 31 included in the same area increases toward the X2 side. That is, as viewed in the Z direction, the light guide plate 2 has a first region R1 and a second region R2 having the same area that are separated from the light sources 71 toward the X2 side (one side in the second direction); the second region R2 is disposed further on the X2 side than the first region R1; and the number of the white resists 31 included in the second region R2 is larger than the number of the white resists 31 included in the first region R1.

A black resist 32 absorbs part of the light 120 propagating in the light guide plate 2. The black resist 32 is applied to the upper surface 42a of the second light-transmitting plate 42 and has a columnar shape extending in the Z direction. The black resist 32 is, for example, a spacer 52 between the light guide plate 2 and the sensor substrate 4. As illustrated in FIG. 1, the black resist 32 is in contact with the first surface 21 of the light guide plate 2 and the upper surface 42a of the second light-transmitting plate 42. As illustrated in FIGS. 4A and 4B, the density of a plurality of the spacers 52 increases as distance from the light sources 71 decreases. That is, as illustrated in FIG. 4A, as viewed in the Z direction, the light guide plate 2 has the first region R1 and the second region R2 having the same area that are separated from the light sources 71 toward the X2 side (one side in the second direction); the second region R2 is disposed further on the X2 side than the first region R1; and the number of the black resists 32 (spacers 52) included in the first region R1 is larger than the number of the black resists 32 (spacers 52) included in the second region R2.

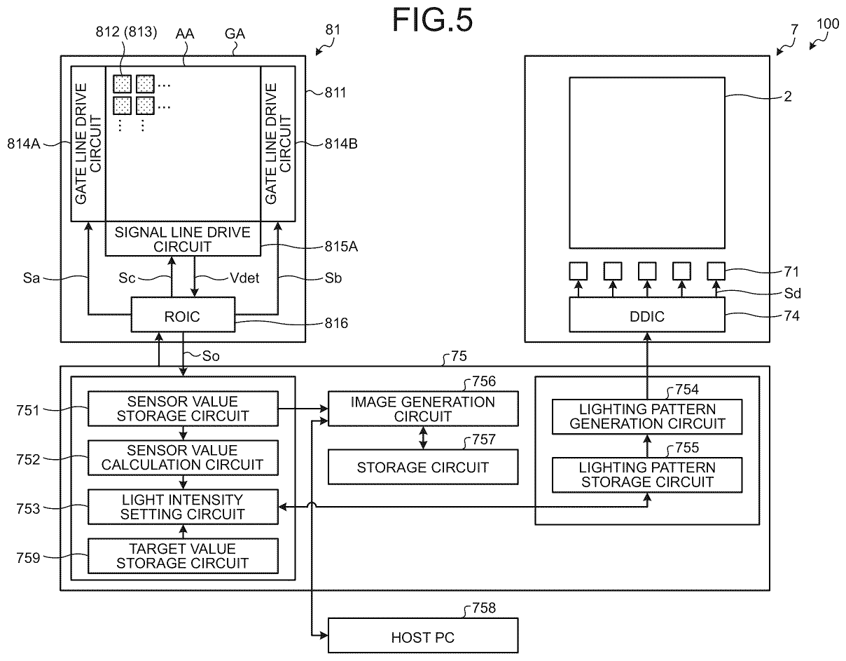

FIG. 5 is a block diagram illustrating a configuration example of the detection device according to the first embodiment. As illustrated in FIG. 5, the detection device 100 includes the optical sensor 81, the light source device 7, and a host integrated circuit (IC) 75 that controls the light source device 7. The optical sensor 81 includes an array substrate 811, a plurality of sensor pixels 812 (photodiodes 813) formed on the array substrate 811, gate line drive circuits 814A and 814B, a signal line drive circuit 815A, and a detection control circuit (ROIC) 816.

The array substrate 811 is formed using a substrate as a base. Each of the sensor pixels 812 is configured with a corresponding one of the photodiodes 813, a plurality of transistors, and various types of wiring.

The array substrate 811 has a detection area AA and a peripheral area GA. The detection area AA is an area provided with the sensor pixels 812 (photodiodes 813). The peripheral area GA is an area between the outer perimeter of the detection area AA and the outer edges of the array substrate 811, and is an area not provided with the sensor pixels 812. The gate line drive circuits 814A and 814B, the signal line drive circuit 815A, and the detection control circuit 816 are provided in the peripheral area GA.

Each of the sensor pixels 812 is an optical sensor that includes the photodiode 813 as a sensor element. Each of the photodiodes 813 outputs an electrical signal corresponding to light emitted thereto.

The detection control circuit 816 is a circuit that supplies control signals Sa, Sb, and Sc to the gate line drive circuits 814A and 814B and the signal line drive circuit 815A, respectively, to control operations of these circuits. The detection control circuit 816 includes a signal processing circuit that processes a detection signal Vdet from each of the photodiodes 813.

The detection control circuit 816 processes the detection signals Vdet from the photodiodes 813, and outputs sensor values So based on the detection signals Vdet to the host IC 75. Through this operation, the detection device 100 detects information on the object to be detected 114.

The light source device 7 includes the light sources 71 and a light-emitting element control circuit (DDIC) 74. As described above, the light sources 71 are disposed so as to face the side surface 23 of the light guide plate 2. The light sources 71 are driven between on (lit state) and off (unlit state) by a command Sd of the light-emitting element control circuit 74.

The host IC 75 includes, as a control circuit for the optical sensor 81, a sensor value storage circuit 751, a sensor value calculation circuit 752, a light intensity setting circuit 753, a target value storage circuit 759, a storage circuit 757, and a host personal computer (PC) 758. The sensor value storage circuit 751 stores therein the sensor values So output from the detection control circuit 816 of the optical sensor 81. The sensor value calculation circuit 752 performs a predetermined calculation process on the sensor values So of the photodiodes 813.

In a light intensity setting mode, the light intensity setting circuit 753 compares the sensor values So detected by the photodiodes 813 with a preset target sensor value So-t acquired from the target value storage circuit 759 to set light intensities of the light sources 71 for detection. The target value storage circuit 759 stores therein the preset target sensor value So-t.

The host IC 75 includes, as a control circuit for the light source device 7, a lighting pattern generation circuit 754 and a lighting pattern storage circuit 755. The lighting pattern storage circuit 755 stores therein information on the light intensity of each of the light sources 71 in the light intensity setting mode.

The lighting pattern generation circuit 754 generates various control signals based on the information on the light intensity in the lighting pattern storage circuit 755. In a detection mode, an image generation circuit 756 generates an image of the object to be detected 114 based on the sensor values So output from the photodiodes 813. The host IC 75 further includes the storage circuit 757.

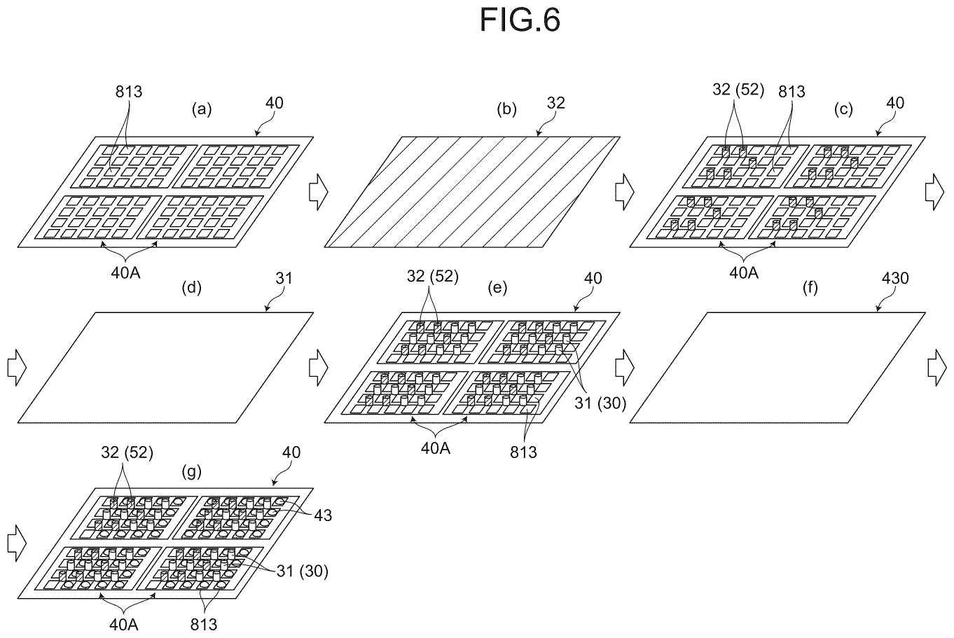

The following describes a manufacturing procedure of the white resists 31, the black resists 32, and the microlenses 43. FIG. 6 is a schematic diagram illustrating a manufacturing process of the detection device according to the first embodiment.

As illustrated in a process (a) in FIG. 6, a large sensor substrate board 40 provided with a plurality (four in the present embodiment) of the sensor substrates 4 is first prepared. That is, one large sensor substrate board 40 includes four unit sensor substrates 40A. As described above, the sensor substrate 4 includes the layered first and second light-transmitting plates 41 and 42, and the photodiodes 813 are formed on the first light-transmitting plate 41.

Then, as illustrated in processes (b) and (c), the film-like black resist 32 is applied to the upper surface 42a of the second light-transmitting plate 42; and as illustrated in FIG. 12 to be explained later, a plurality of the black resists 32 illustrated in the process (c) are provided by irradiating places where the black resists 32 are to remain, for example, with a laser beam 123.

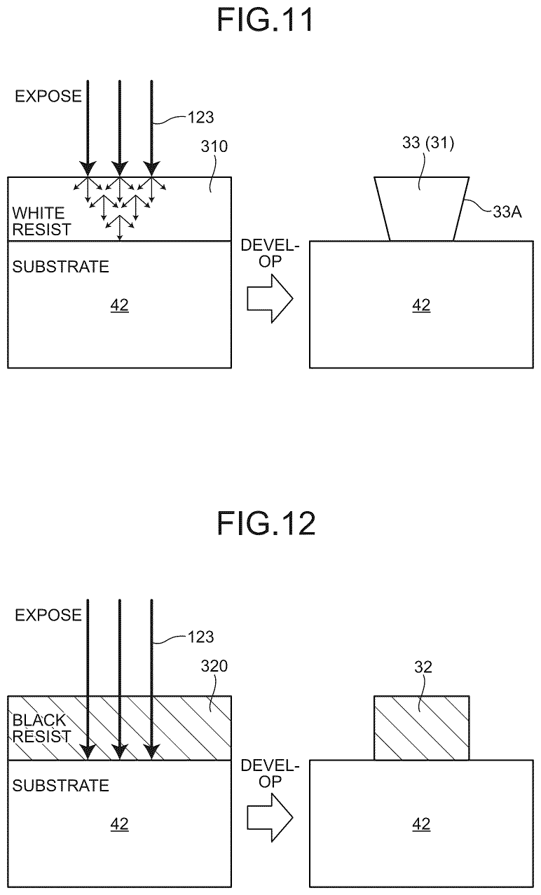

Then, as illustrated in processes (d) and (e), the film-like white resist 31 is applied to the upper surface 42a of the second light-transmitting plate 42; and as illustrated in FIG. 11 to be explained later, a plurality of the white resists 31 illustrated in the process (e) are provided by irradiating places where the white resists 31 are to remain, for example, with the laser beam 123.

Then, as illustrated in processes (f) and (g), a film-like lens resin 430 is applied to the upper surface 42a of the second light-transmitting plate 42; and the microlenses 43 illustrated in the process (g) are provided by irradiating places where the microlenses 43 are to remain, for example, with light.

After manufacturing the sensor substrate 4 as described above, the light guide plate 2 is attached to the upper side of the sensor substrate 4 as illustrated in FIG. 1, and the light sources 71 are disposed on a lateral side of the light guide plate 2 to complete the detection device 100 according to the first embodiment. Consequently, the white resists 31 and the black resists 32 are bonded to the upper surface 42a of the second light-transmitting plate 42 and are merely in contact with the first surface 21 of the light guide plate 2.

As described above, the detection device 100 according to the present embodiment includes: the optical sensor 81 including the photodiodes 813 (photodetection elements) arranged in a planar configuration; the light guide plate 2 disposed on the Z1 side of the optical sensor 81 so as to overlap the optical sensor 81; the light sources 71; and the light scatterers 30. The light scatterers 30 are an integrally molded product separate from the light guide plate 2 and are provided in a state of being in contact with the light guide plate 2.

When the light 120 from the light sources 71 that is incident from the lateral side of the light guide plate 2 and propagates in the light guide plate 2 hits the light scatterers 30, the light 120 is scattered by the light scatterers 30. Part of this scattered light 121 exits through the light guide plate 2 toward the object to be detected 114, and light from the object to be detected 114 enters the photodiodes 813 through the light guide plate 2.

Therefore, compared with the configuration described in the background art in which the light diffusion structure having a triangular section is provided on the surface of the light guide plate 2 facing on the photodiodes, the light that has been refracted by the light scatterers 30 is less likely to enter the photodiodes 813. Therefore, according to the present embodiment, the detection device 100 capable of achieving good accuracy of detection can be provided.

The number of the white resists 31 (light scatterers 30) included in the second region R2 is larger than the number of the white resists 31 included in the first region R1.

The amount of the light 120 propagating in the light guide plate 2 is smaller as distance from the light sources 71 increases. By increasing the density of the light scatterers 30 as distance from the light sources 71 increases, the amount of the light 120 scattered by the light scatterers 30 becomes larger in the region farther from the light sources 71. Therefore, when the light guide plate 2 is viewed in the Z direction, the amount of the scattered light 120 is more equalized over the entire area of the light guide plate 2.

The number of the black resists 32 (spacers 52) included in the first region R1 is larger than the number of the black resists 32 (spacers 52) included in the second region R2.

By using the white resists 31 as the light scatterers 30 and the black resists 32 as the spacers 52, more of the white resists 31 can be arranged in regions farther from the light sources 71 when the light guide plate 2 is viewed in the Z direction, as illustrated in FIG. 4A.

The optical filter 82 having the light guide path 821 and the light-blocking portion 822 is provided between the light guide plate 2 and the optical sensor 81. The light guide path 821 overlaps the photodiode 813 as viewed in the Z direction.

The light 120 that has passed from the object to be detected 114 through the light guide plate 2 can easily enter the photodiode 813 through the light guide path 821. Therefore, good accuracy of detection can be achieved.

The microlens 43 is disposed in the X direction with respect to the light scatterer 30.

In other words, the microlens 43 and the light scatterer 30 are aligned when viewed in the Z direction. Therefore, the thickness in the Z direction of the detection device 100 is made smaller.

The optical filter 82 that limits a light incident path onto the photodiode 813 is provided.

Since the light incident on one photodiode 813 can be limited by providing the optical filter 82, good accuracy of detection can be achieved.

### Second Embodiment

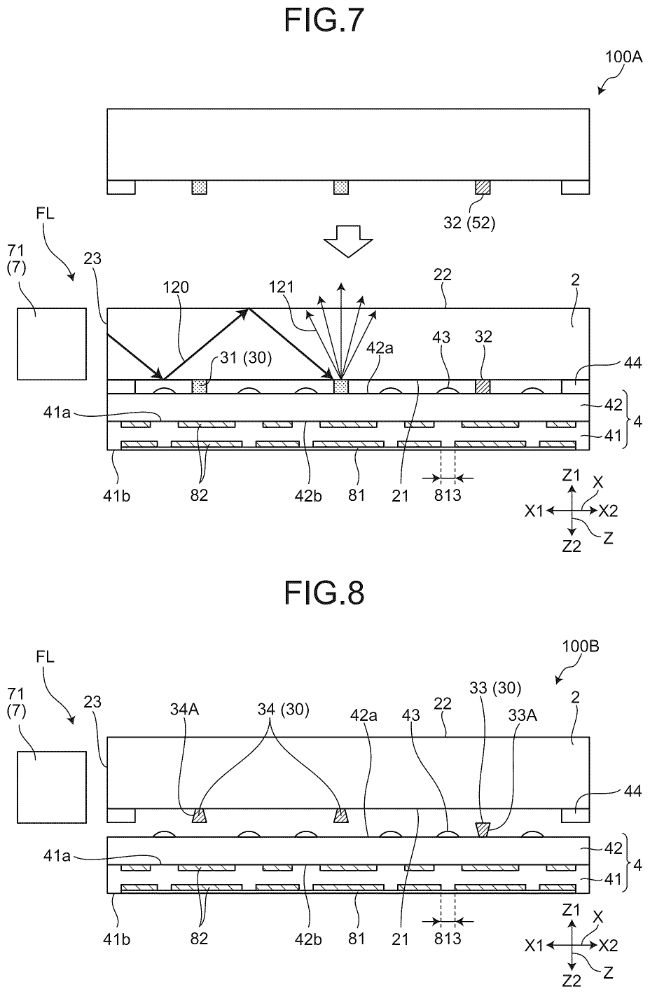

The following describes a second embodiment. FIG. 7 is a schematic view illustrating a detection device according to the second embodiment.

In the detection device 100 according to the first embodiment described above, the white resists 31 and the black resists 32 are bonded to the upper surface 42a of the second light-transmitting plate 42 and are merely in contact with the first surface 21 of the light guide plate 2.

In contrast, in a detection device 100A according to the second embodiment, the white resists 31 and the black resists 32 are bonded to the first surface 21 of the light guide plate 2 and are merely in contact with the upper surface 42a of the second light-transmitting plate 42.

That is, after applying the white resists 31 and the black resists 32 to the first surface 21 of the light guide plate 2 according to the procedure in FIG. 6 described above, the light guide plate 2 provided with the white resists 31 and the black resists 32 is attached to the sensor substrate 4, as illustrated in FIG. 7.

As described above, in the detection device 100A according to the present embodiment, in the same way as in the first embodiment, the light scatterers 30 are an integrally molded product separate from the light guide plate 2 and are provided in the state of being in contact with the light guide plate 2. Therefore, since the light 120 refracted by the light scatterers 30 is less likely to enter the photodiode 813, the detection device capable of achieving good accuracy of detection can be provided according to the present embodiment.

### First Modification

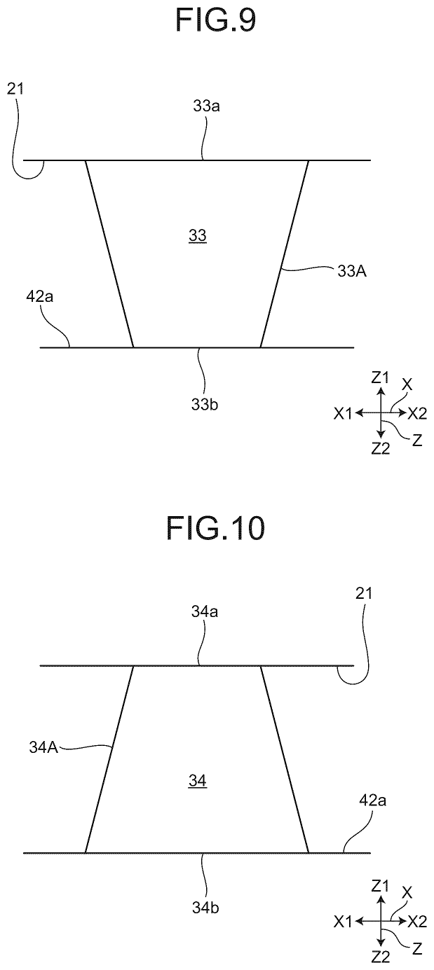

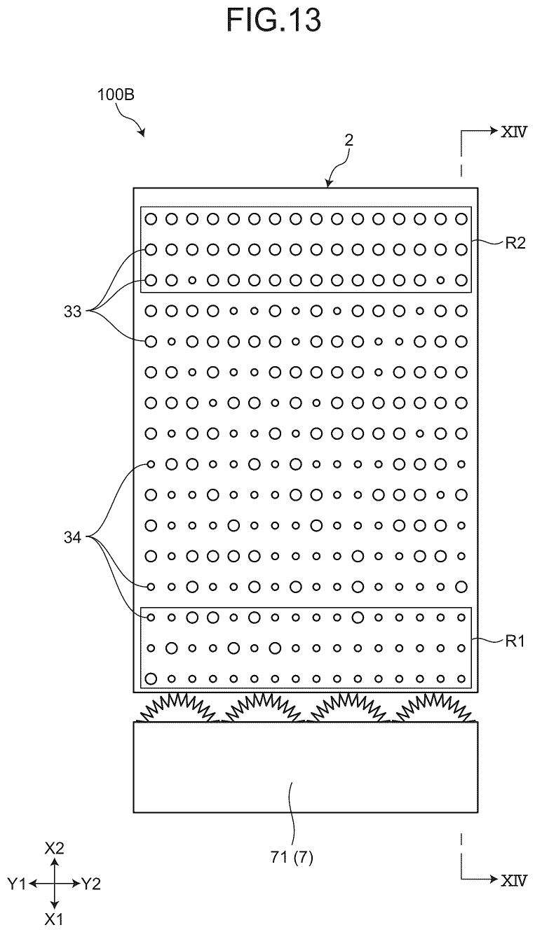

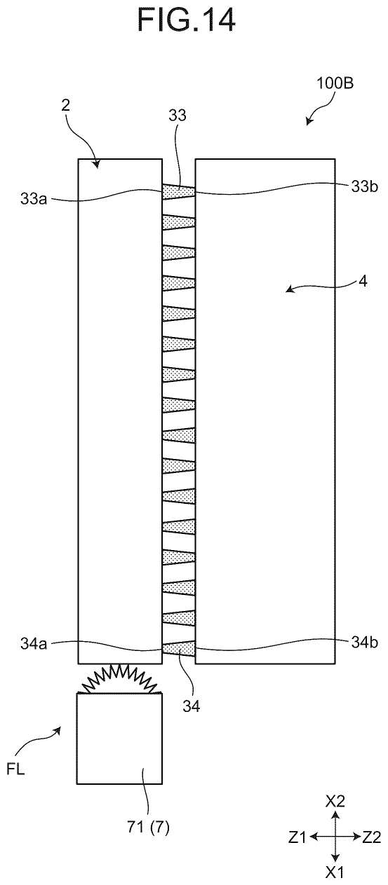

The following describes a first modification. FIG. 8 is a schematic view illustrating a detection device according to the first modification. FIG. 9 is a schematic view illustrating a first light scatterer having a shape of a first taper. FIG. 10 is a schematic view illustrating a second light scatterer having a shape of a second taper. FIG. 11 is a schematic diagram illustrating a manufacturing process of the light scatterer using the white resist. FIG. 12 is a schematic diagram illustrating the manufacturing process of the light scatterer using the black resist. FIG. 13 is a plan view of the detection device according to the first modification. FIG. 14 is a sectional view taken along XIV-XIV in FIG. 13.

In the first modification, the light scatterers 30 include a first light scatterer 33 and a second light scatterer 34. The first light scatterer 33 and the second light scatterer 34 are each the white resist 31. As illustrated in FIG. 9, the first light scatterer 33 has a shape of a first taper 33A that has a columnar shape extending in the Z direction and has a diameter increasing as distance from the light guide plate 2 decreases (toward the Z1 side). The first light scatterer 33 has a shape of a circular truncated cone, for example. The first light scatterer 33 has an upper surface 33a and a lower surface 33b. The upper surface 33a is in contact with the first surface 21 of the light guide plate 2. The lower surface 33b is in contact with the upper surface 42a of the second light-transmitting plate 42. As illustrated in FIG. 8, the first light scatterer 33 is formed on the upper surface 42a of the second light-transmitting plate 42. As illustrated in FIG. 11, a white resist material 310 is applied to the upper surface 42a of the second light-transmitting plate 42 and then is irradiated with the laser beam 123, which causes the irradiated part to be reacted and developed to form the first light scatterer 33 on the upper surface 42a.

As illustrated in FIG. 12, a black resist material 320 is applied to the upper surface 42a of the second light-transmitting plate 42 and then is irradiated with the laser beam 123, which causes the irradiated part to be reacted and developed to form the black resist 32 on the upper surface 42a. The black resist 32 has a circular cylindrical shape, for example.

As illustrated in FIG. 10, the second light scatterer 34 has a shape of a second taper 34A that has a columnar shape extending in the Z direction and has a diameter decreasing as distance from the light guide plate 2 decreases (toward the Z1 side). The second light scatterer 34 has a shape of a circular truncated cone, for example. The second light scatterer 34 has an upper surface 34a and a lower surface 34b. The upper surface 34a is in contact with the first surface 21 of the light guide plate 2. The lower surface 34b is in contact with the upper surface 42a of the second light-transmitting plate 42. As illustrated in FIG. 8, the second light scatterer 34 is formed on the first surface 21 of the light guide plate 2. The second light scatterer 34 is formed by applying the white resist material 310 to the first surface 21 of the light guide plate 2 and then irradiating the white resist material 310 with the laser beam 123.

As illustrated in FIGS. 13 and 14, as viewed in the Z direction, the light guide plate 2 has the first region R1 and the second region R2 having the same area that are separated from the light sources 71 toward the X2 side (one side in the second direction); the second region R2 is disposed further on the X2 side than the first region R1; and the number of the first light scatterers 33 included in the second region R2 is larger than the number of the first light scatterers 33 included in the first region R1. In other words, the density of the first light scatterers 33 increases from the X1 side toward the X2 side.

As described above, in a detection device 100B according to the first modification, the light scatterers 30 include a plurality of the first light scatterers 33 that have a columnar shape extending in the Z direction and have a diameter increasing as distance from the light guide plate 2 decreases.

For example, the area of the upper surface of the first light scatterer 33 in contact with the light guide plate 2 is larger than that of a circular cylindrical light scatterer extending in the Z direction and a light scatterer having a diameter decreasing as distance from the light guide plate 2 decreases. Therefore, according to the present modification, the amount of the light scattered on the upper surface of the first light scatterer 33 increases.

The light scatterers 30 include the first light scatterers 33 and the second light scatterers 34 that have a columnar shape extending in the Z direction and have a diameter decreasing as distance from the light guide plate 2 decreases. The density of the first light scatterers 33 increases as distance from the light sources 71 increases, and the density of the second light scatterers 34 increases as distance from the light sources 71 decreases.

The area of the upper surface of the first light scatterer 33 in contact with the light guide plate 2 is larger than the area of the upper surface of the second light scatterer 34 in contact with the light guide plate 2. The amount of the light scattered by the first light scatterer 33 is larger than the amount of the light scattered by the second light scatterer 34. The amount of the light 120 propagating in the light guide plate 2 is smaller as distance from the light sources 71 increases. Therefore, when the light guide plate 2 is viewed in the Z direction, the amount of the scattered light 120 is more equalized over the entire area of the light guide plate 2.

### Second Modification

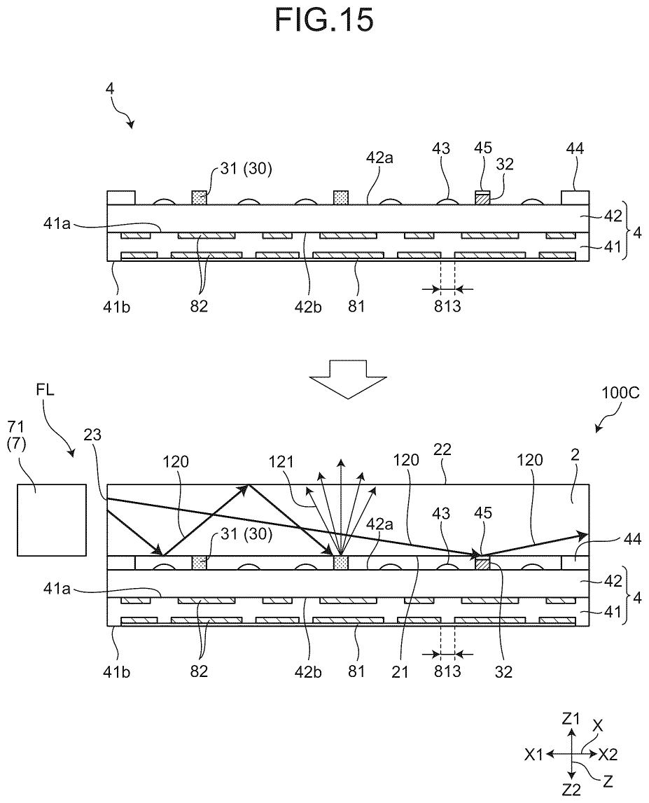

The following describes a second modification. FIG. 15 is a schematic view illustrating a detection device according to the second modification.

The second modification differs from the first embodiment in that a reflective film 45 is provided on the upper surface of the black resist 32. A brief description will be given below. As illustrated in the upper part of FIG. 15, the white resist 31 and the black resist 32 are bonded to the upper surface 42a of the second light-transmitting plate 42, and the reflective film 45 is formed by being applied to the upper surface of the black resist 32. The light guide plate 2 is then attached on top of the sensor substrate 4. Consequently, the white resist 31 and the reflective film 45 are merely in contact with the first surface 21 of the light guide plate 2.

As described above, in the detection device 100C according to the second modification, the reflective film 45 is provided on the upper surface of the black resist 32. The black resist 32 absorbs the light 120, but by providing the reflective film 45 on the black resist 32, the region where the black resist 32 is disposed also reflects (scatters) the light 120.

### Third Modification

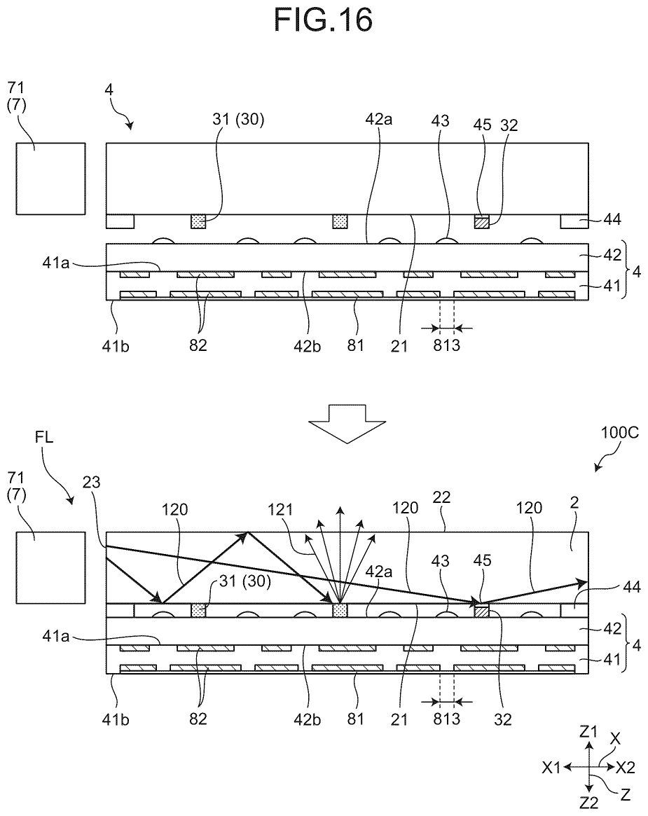

The following describes a third modification. FIG. 16 is a schematic view illustrating a detection device according to the third modification.

The third modification differs from the second embodiment in that the reflective film 45 is provided on the upper surface of the black resist 32. A brief description will be given below. As illustrated in the upper part of FIG. 16, the white resist 31 is bonded to the first surface 21 of the light guide plate 2. The reflective film 45 is formed on the first surface 21 of the light guide plate 2, and the black resist 32 is formed on the Z2 side of the reflective film 45. The light guide plate 2 is then attached on top of the sensor substrate 4. Consequently, the white resist 31 and the black resist 32 are merely in contact with the upper surface 42a of the second light-transmitting plate 42.

Also, in a detection device 100C according to the third modification, the reflective film 45 is provided on the upper surface of the black resist 32 as described above. The black resist 32 absorbs the light 120. Therefore, portions where the black resists 32 provided with the reflective film 45 are disposed also reflect (scatter) the light 120.

### Third Embodiment

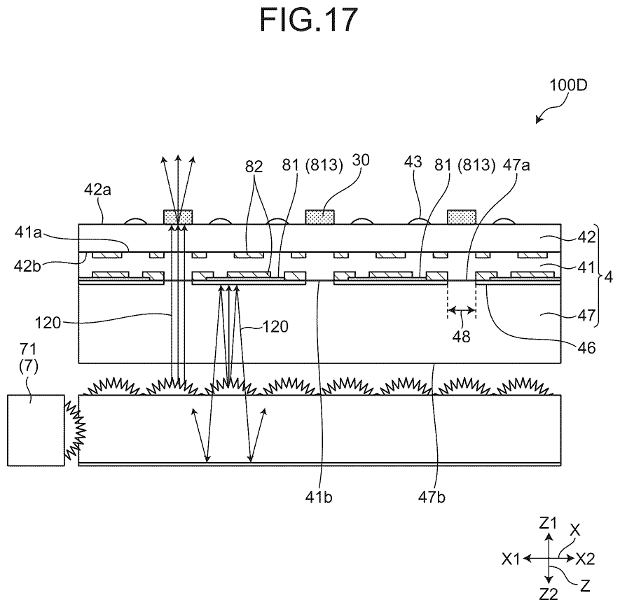

The following describes a third embodiment. FIG. 17 is a schematic view illustrating a detection device according to the third embodiment.

A detection device 100D according to the third embodiment includes a light-blocking layer 46 that has openings 48. A specific description will be given below.

The light-blocking layer 46 is provided between the photodiodes 813 and a third light-transmitting plate 47. The third light-transmitting plate 47 is stacked on the lower side of the first light-transmitting plate 41. The photodiode 813 is stacked on the upper side of the light-blocking layer 46. The light-blocking layer 46 is provided with the openings 48. The light scatterers 30 overlapping the openings 48 are provided as viewed in the Z direction. The light scatterers 30 are provided on the upper surface 42a of the second light-transmitting plate 42. The light scatterers 30 do not overlap the photodiodes 813 as viewed in the Z direction. The microlenses 43 overlap the photodiodes 813 as viewed in the Z direction.

As described above, in the detection device 100D according to the third embodiment, the detection device 100D includes the optical sensor 81 including the photodiodes 813 (photodetection elements) arranged in a planar configuration, the light guide plate 2 disposed on the Z2 side of the optical sensor 81 so as to overlap the optical sensor 81, the light sources 71, and the light-blocking layer 46 provided between the photodiodes 813 and the light guide plate 2. The light-blocking layer 46 has the openings 48.

By providing the openings 48 in the light-blocking layer 46, the light that travels from the light guide plate 2 toward the object to be detected 114 can be limited to light passing through the openings 48.

The light scatterers 30 are provided overlapping the openings 48 as viewed in the Z direction. This configuration allows the light that travels from the light guide plate 2 toward the object to be detected 114 to be transmitted through the openings 48 and scattered by the light scatterers 30.

The light scatterers 30 do not overlap the photodiodes 813 as viewed in the Z direction.

If the light scatterers 30 overlap the photodiodes 813 as viewed in the Z direction, the light from the object to be detected 114 toward the photodiodes 813 is scattered by the light scatterers 30. Therefore, by providing the light scatterers 30 such that the light scatterers 30 do not overlap the photodiodes 813 as viewed in the Z direction, the light from the object to be detected 114 toward the photodiodes 813 is restrained from being scattered by the light scatterers 30.

### Fourth Embodiment and Fourth Modification

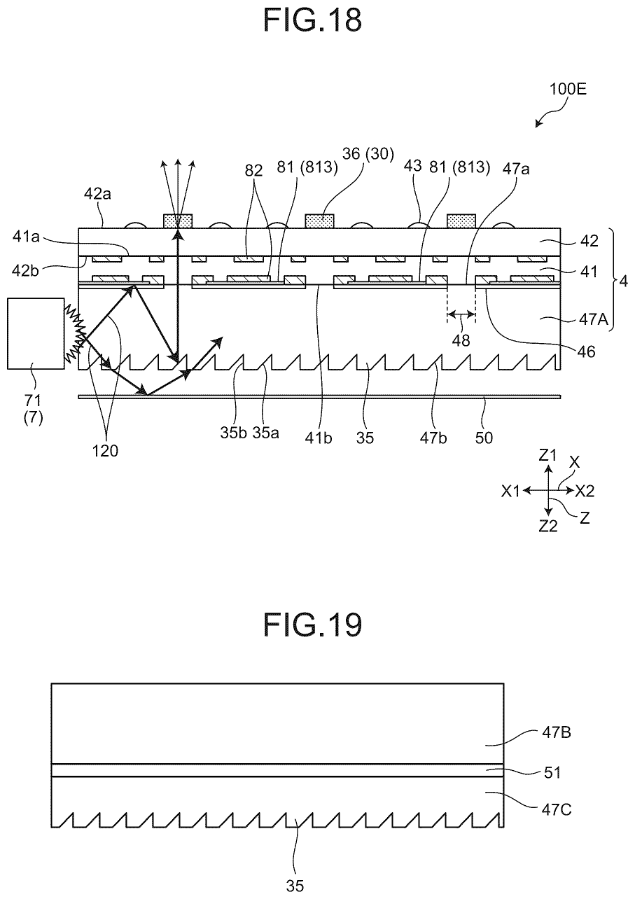

The following describes a fourth embodiment. FIG. 18 is a schematic view illustrating a detection device according to the fourth embodiment. FIG. 19 is a schematic view illustrating a light guide plate according to a fourth modification.

In a detection device 100E according to the fourth embodiment, a light-transmitting plate 47A is stacked on the lower side of the first light-transmitting plate 41, and a first diffuser 35 is provided on the lower surface 47b of the light-transmitting plate 47A. The first diffuser 35 is triangular notches as viewed in the Y direction that are dented toward the Z1 side (upper side). That is, the first diffuser 35 has a shape of prisms. The first diffuser 35 faces inclined surfaces 35a and vertical surfaces 35b. The vertical surfaces 35b extend in the Z direction. The inclined surfaces 35a extend in a direction intermediate between the Z1 and X2 sides. The first diffuser 35 diffuses the light 120 propagating in the light guide plate 2 toward the Z1 side.

Second diffusers 36 and the microlenses 43 are provided on the upper surface 42a of the second light-transmitting plate 42. The second diffusers 36 overlap the openings 48 of the light-blocking layer 46 as viewed in the Z direction. The microlenses 43 are arranged in the X direction with respect to the second diffusers 36.

A reflective plate 50 is disposed on the lower side of the light-transmitting plate 47A. The light 120 from the light sources 71 hits the reflective plate 50 and is reflected by the reflective plate 50 after passing through the light guide plate 2, and enters the light guide plate 2 again.

The first diffuser 35 is directly formed on the lower surface 47b of the light-transmitting plate 47A in the fourth embodiment. However, as illustrated in FIG. 19 according to the fourth modification, the first diffuser 35 may be formed on the lower surface of a light-transmitting plate 47C, and the light-transmitting plate 47C may be bonded to the lower surface of a light-transmitting plate 47B with an adhesive layer 51 interposed therebetween.

As described above, in the fourth embodiment and the fourth modification, the detection device 100E includes: the optical sensor 81 including the photodiodes 813 (photodetection elements) arranged in a planar configuration; the light guide plate 2 disposed on the Z2 side of the optical sensor 81 so as to overlap the optical sensor 81; the light sources 71; and the light-blocking layer 46 provided between the photodiodes 813 and the light guide plate 2. The light-blocking layer 46 has the openings 48. The surface on the Z2 side of the light guide plate 2 is provided with the first diffuser 35 that diffuses, toward the Z1 side, the light propagating in the light guide plate 2.

Thus, since the first diffuser 35 is provided on the surface on the Z2 side of the light guide plate 2, the light propagating in the light guide plate 2 can be diffused toward the Z1 side.

The detection device 100E includes the second diffusers 36 and the microlenses 43. The microlenses 43 are arranged in the X direction with respect to the second diffusers 36.

Since the second diffusers 36 are provided on the Z1 side of the light guide plate 2, light traveling toward the Z1 side in the light guide plate 2 can be diffused by the second diffusers 36.

The first diffuser 35 has a shape of prisms.

This configuration allows the first diffuser 35 to change the traveling direction of the light propagating in the light guide plate 2 to a direction toward the Z1 side.

The second diffusers 36 overlap the openings 48 as viewed in the Z direction.

With this configuration, the light that travels from the light guide plate 2 toward the object to be detected 114 is transmitted through the openings 48 and scattered by the second diffusers 36.

### Fifth Embodiment

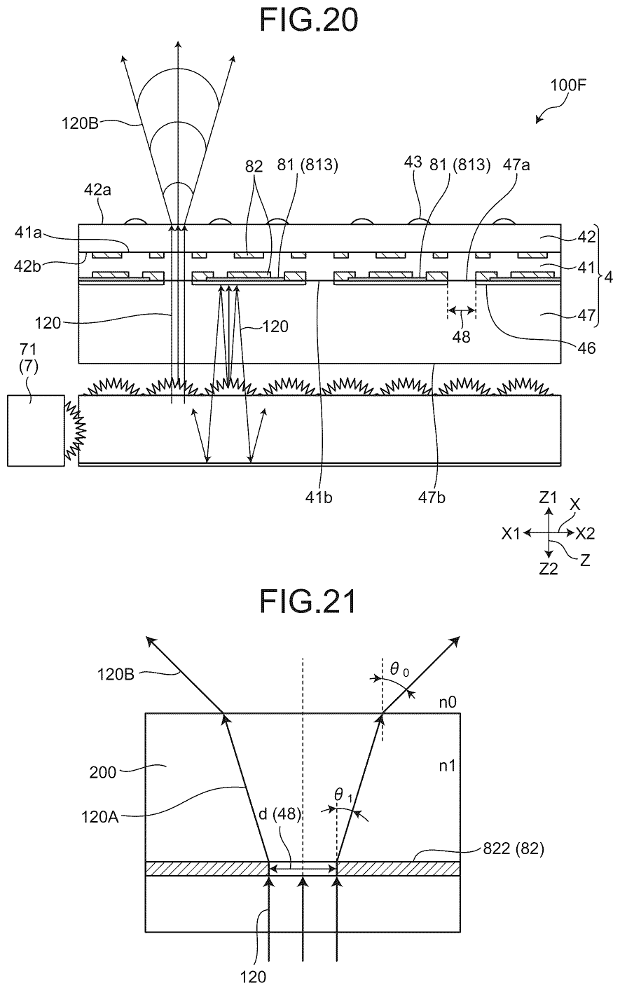

The following describes a fifth embodiment. FIG. 20 is a schematic view illustrating a detection device according to the fifth embodiment. FIG. 21 is a schematic view illustrating a spreading state of diffracted light. As illustrated in FIG. 20, in a detection device 100F according to the fifth embodiment, light that exits from the upper surface 42a of the second light-transmitting plate 42 is diffracted light 120B. The following describes conditions for generating the diffracted light 120B with reference to FIG. 21 and Table 1.

When each of the openings 48 illustrated in FIG. 21 is the circular opening 48 in plan view, a spread angle θ1 of diffracted light 120A from the opening 48 is expressed by Expression 1 below that expresses the size of the Airy disk. 01 denotes the spread angle of the diffracted light 120A from the opening 48; A denotes the wavelength of the incident light; and d denotes the diameter of the opening 48.

$$sin {θ}_{1} = 1.22 \frac{λ}{d} \qquad ( 1 )$$

The opening 48 is assumed to be present in a medium such as a resin, and the diffracted light 120B is assumed to exit from the medium into the air. The spread angle of the diffracted light 120B in air is expressed by Expression 2 from Snell's law. θ₀ denotes the spread angle of the diffracted light 120B in air; n₀ denotes the refractive index of air; and n₁ denotes the refractive index of the medium that includes a collimator.

$$\frac{sin {θ}_{0}}{sin {θ}_{1}} = \frac{{n}_{1}}{{n}_{0}} \qquad ( 2 )$$

Consequently, Expression 3 below is derived.

$$sin {θ}_{0} = 1.22 \frac{{n}_{1}}{{n}_{0}} \frac{λ}{d} \qquad ( 3 )$$

Assuming that n₀=1.0 and n₁=1.5, the spread angle of the diffracted light 120B in air is as illustrated in Table 1 below.

TABLE 1

| λ/d | θ₀ (deg) |
|---|---|
| 1.0 | — |
| 1.5 | — |
| 2.0 | 66.2 |
| 2.5 | 47.1 |
| 3.0 | 37.6 |
| 3.5 | 31.5 |
| 4.0 | 27.2 |
| 4.5 | 24.0 |
| 5.0 | 21.5 |
| 5.5 | 19.4 |
| 6.0 | 17.8 |
| 6.5 | 16.4 |
| 7.0 | 15.2 |
| 7.5 | 14.1 |
| 8.0 | 13.2 |
| 8.5 | 12.4 |
| 9.0 | 11.7 |
| 9.5 | 11.1 |
| 10.0 | 10.5 |

Referring to Table 1, the spread angle of diffracted light 120B is preferably from 15 degrees to 65 degrees for the reason that too large a spread angle of the diffracted light 120B causes a loss of light due to reflection at the medium interface, while too small a spread angle of the light degrades uniformity of irradiation. According to Table 1, the value of λ/d at which the spread angle of the emitted light is from 15 degrees to 65 degrees is from 2.0 to 7.0. Therefore, it can be understood that the value of λ/d is preferably from 2.0 to 7.0.

As described above, in the fifth embodiment, the opening 48 is circular as viewed in the Z direction. The ratio λ/d of the wavelength λ of the light relative to the diameter d of the opening 48 is 2.0 to 7.0.

By setting the relation between the diameter d of the opening 48 and the wavelength λ of the light within the above-mentioned numerical range, the light emitted from the upper surface 42a of the second light-transmitting plate 42 to the air is appropriately diffracted with a larger spread angle.

### Sixth Embodiment

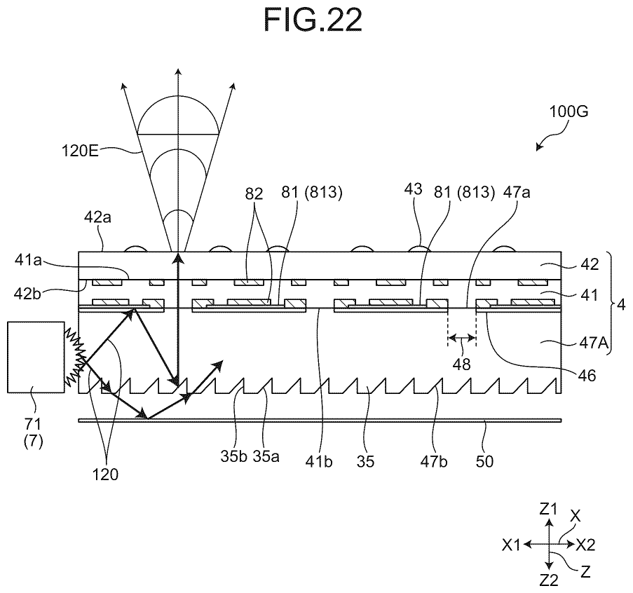

The following describes a sixth embodiment. FIG. 22 is a schematic view illustrating a detection device according to the sixth embodiment.

A detection device 100G according to the sixth embodiment exhibits a configuration obtained by removing the second diffusers 36 from the detection device 100E according to the fourth embodiment illustrated in FIG. 18. Hence, the light 120 propagating in the light guide plate 2 is diffused toward the Z1 side by the first diffuser 35 and passes through the openings 48. The diameter of the opening 48 satisfies the conditions described in the fifth embodiment, so that the light emitted from the upper surface 42a of the second light-transmitting plate 42 becomes diffracted light 120E.

As described above, in the sixth embodiment, since the diameter d of the opening 48 satisfies the conditions described in the fifth embodiment, the ratio λ/d of the wavelength λ of the light relative to the diameter d of the opening 48 is 2.0 to 7.0.

By setting the relation between the diameter d of the opening 48 and the wavelength λ of the light within the above-mentioned numerical range, the light that exits from the upper surface 42a of the second light-transmitting plate 42 to the air is appropriately diffracted with a larger spread angle.

### Fifth Modification

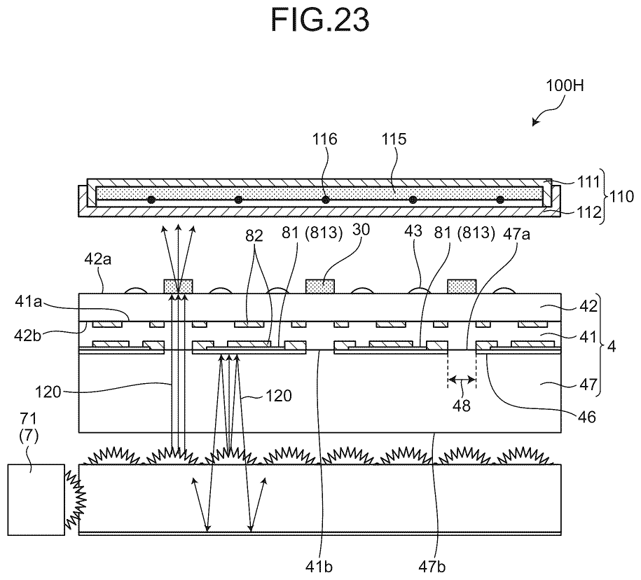

The following describes a fifth modification. FIG. 23 is a schematic view illustrating a detection device according to the fifth modification.

A detection device 100H according to the fifth modification handles microorganisms 116 accommodated in a container 110 as the object to be detected. The container 110 includes a placement substrate 111 and a cover member 112. The container 110 is a Petri dish, for example. The container 110 has a light-transmitting property. The container 110 is placed upside down relative to a normal container. That is, the container 110 is placed such that the placement substrate 111 is placed on the upper side and the cover member 112 is placed on the lower side. A culture medium 115 is provided on the lower side of the placement substrate 111; and the microorganisms 116, such as bacteria or cells, are put on the culture medium 115 (surface on the lower side of the culture medium 115).

As described above, according to the fifth modification, the object to be detected 114 obtained by putting the microorganisms 116 on the culture medium 115 can be applied.

What is claimed is:

1. A detection device comprising:
an optical sensor comprising a plurality of photodetection elements arranged in a planar configuration;
a light guide plate that is disposed on one side in a first direction of the optical sensor so as to overlap the optical sensor and has a light-transmitting property;
a light source that is disposed adjacent to the light guide plate in a second direction intersecting the first direction and is configured to emit light to a side surface of the light guide plate; and
a plurality of light scatterers that are arranged between the optical sensor and the light guide plate so as not to overlap the photodetection elements as viewed in the first direction and are configured to scatter the light propagating in the light guide plate.

2. The detection device according to claim 1, wherein
the light guide plate comprises a first region and a second region having a same area that are separated from the light source toward one side in the second direction as viewed in the first direction,
the second region is disposed further on the one side in the second direction than the first region, and
the number of the light scatterers included in the second region is larger than the number of the light scatterers included in the first region.

3. The detection device according to claim 2, wherein the light scatterers are first light scatterers that have a columnar shape extending in the first direction and have a diameter increasing as distance from the light guide plate decreases.

4. The detection device according to claim 1, comprising a plurality of spacers arranged between the light guide plate and the optical sensor, wherein
the light guide plate comprises a first region and a second region having a same area that are separated from the light source toward one side in the second direction as viewed in the first direction,
the second region is disposed further on the one side in the second direction than the first region, and
the number of the spacers included in the first region is larger than the number of the spacers included in the second region.

5. The detection device according to claim 3, wherein
the light scatterers comprise:
a plurality of the first light scatterers; and
a plurality of second light scatterers that have a columnar shape extending in the first direction and have a diameter decreasing as distance from the light guide plate decreases, and
the light guide plate comprises a first region and a second region having a same area that are separated from the light source toward one side in the second direction as viewed in the first direction,
the second region is disposed further on the one side in the second direction than the first region,
the number of the first light scatterers included in the first region is smaller than the number of the first light scatterers included in the second region, and
the number of the second light scatterers included in the first region is larger than the number of the second light scatterers included in the second region.

6. The detection device according to claim 1, wherein
an optical filter comprising light guide paths and a light-blocking portion is provided between the light guide plate and the optical sensor, and
the light guide paths overlap the photodetection elements as viewed in the first direction.

7. The detection device according to claim 6, comprising microlenses that overlap the photodetection elements as viewed in the first direction and are configured to focus, toward the photodetection elements, light traveling from the other side toward the one side in the first direction, wherein
the microlenses are arranged in the second direction intersecting the first direction with respect to the light scatterers.

8. A detection device comprising:
an optical sensor comprising a plurality of photodetection elements arranged in a planar configuration;
a light guide plate that is disposed on another side in a first direction of the optical sensor so as to overlap the optical sensor and has a light-transmitting property;
a light source that is disposed adjacent to the light guide plate in a second direction intersecting the first direction and is configured to emit light to a side surface of the light guide plate; and
a light-blocking layer provided between the photodetection elements and the light guide plate, wherein
the light-blocking layer has an opening.

9. The detection device according to claim 8, wherein
the opening is circular as viewed in the first direction, and
a ratio λ/d of a wavelength λ of the light relative to a diameter d of the opening is 2.0 to 7.0.

10. The detection device according to claim 8, comprising a light diffuser that overlaps the opening as viewed in the first direction.

11. The detection device according to claim 8, comprising an optical filter configured to limit light incident paths onto the photodetection elements.

12. The detection device according to claim 10, wherein the light diffuser does not overlap the photodetection elements as viewed in the first direction.

13. A detection device comprising:
an optical sensor comprising a plurality of photodetection elements arranged in a planar configuration;
a light guide plate that is disposed on another side that is opposite to one side in a first direction of the optical sensor so as to overlap the optical sensor and has a light-transmitting property;
a light source that is disposed adjacent to the light guide plate in a second direction intersecting the first direction and is configured to emit light to a side surface of the light guide plate; and
a light-blocking layer provided between the photodetection elements and the light guide plate, wherein
the light-blocking layer has an opening, and
a surface on the other side in the first direction of the light guide plate is provided with a first diffuser configured to diffuse, toward the one side in the first direction, the light that propagates in the light guide plate.

14. The detection device according to claim 13, comprising:
a second diffuser that is arranged on the one side in the first direction of the optical sensor and is configured to diffuse the light toward the one side in the first direction; and
a microlens that overlaps the photodetection elements as viewed in the first direction, wherein
the microlens is arranged in the second direction intersecting the first direction with respect to the second diffuser.

15. The detection device according to claim 13, wherein the first diffuser has a shape of a prism.

16. The detection device according to claim 14, wherein the second diffuser overlaps the opening as viewed in the first direction.
